(19) United States
(12) Patent Application Publication
(10) Pub. No.: US 2026/0266874 A1
(43) Pub. Date: Sep. 10, 2026

(54) MANUFACTURING PROCESS FOR PROBE SOCKET SET

(71) Applicant: UNITECH TECHNOLOGY YEH CORPORATION, Tainan City (TW)

(72) Inventor: Kuo-Cheng CHIEN, Tainan (TW)

(21) Appl. No.: 19/074,064

(22) Filed: Mar. 7, 2025

(51) Int. Cl. G01R 3/00; B29C 45/00; G01R 1/04

(52) U.S. Cl. CPC G01R 3/00; B29C 45/0001; G01R 1/0441

(57) ABSTRACT

A manufacturing process for a probe socket set is performed by molding equipment and has steps of forming a socket base and forming a positioning frame. A socket base shaped as a flat board and having multiple probe holes arranged in an array is molded via a base mold of the molding equipment. The socket base is placed in a frame mold, and a positioning frame surrounding the socket base is molded via the molding equipment. The socket base with less thickness variation is formed firstly to enhance dimensional accuracy of the probe holes in the socket base. Accordingly, the probe socket set with good dimensional accuracy of the probe holes in the socket base is manufactured with low manufacturing cost and short manufacturing period.

### BACKGROUND OF THE INVENTION

### 1. Field of the Invention

The present invention relates to a method for manufacturing a probe socket set, and more particularly to a manufacturing process for a probe socket set.

### 2. Description of the Prior Art

In conventional semiconductor test equipment, a test connector is configured for functional testing of semiconductors. The test connector comprises a circuit board and a probe socket set mounted on the circuit board. The probe socket set is configured to hold multiple probes in an array arrangement. In the test of a semiconductor, the semiconductor is placed on the probe socket set and electrically connected to the circuit board via the probes mounted on the probe socket set for testing the semiconductor.

The probe socket set comprises multiple socket components stacked with each other. The socket components may include a positioning base configured to keep the semiconductor in position, a socket plate disposed below the positioning base, and a socket board disposed below the socket plate and configured to connect with the circuit board. The positioning base, the socket plate, and the socket board each have a respective socket base and a respective positioning frame surrounding the socket base. Multiple probe holes in an array arrangement are formed through the socket base. The positioning frame has multiple pins and multiple pin holes. When the socket components are stacked with one another, the socket components are kept in position via engagements of the pins and the pin holes of the positioning frames thereof. Whereby, the probe holes of the multiple socket components may be aligned with and communicate with one another to allow the probes to be respectively mounted through the probe holes of the multiple socket components.

To ensure that the probe holes of each socket component are respectively aligned with the probe holes of the other socket components, each socket component is required to have good accuracy in position and in dimension. If the socket component is directly and integrally formed with the probe holes in the socket base and the positioning structures at the positioning frame by a single molding process, due to large thickness variation between the socket base and the positioning frame, accuracy of finished components is poor, resulting in misalignment of the probe holes of the socket components.

Therefore, in a conventional method for manufacturing a probe socket set, the conventional method comprises a step of forming configuration of the socket base and the positioning frame by molding and a step of forming probe holes by precision drilling. However, as the probe holes of each socket component are numerous and densely distributed, it takes a longer processing period to form the probe holes. If defects occur in the drilling process, the defective socket component needs to be remanufactured. As the result, the operating and manufacturing costs of the probe socket set are higher in the conventional method.

To overcome the shortcomings, the present invention provides a manufacturing process for a probe socket set to mitigate or obviate the aforementioned problems.

### SUMMARY OF THE INVENTION

The main objective of the present invention is to provide a manufacturing process for a probe socket set to mitigate the shortcomings of the conventional manufacturing method with a long processing period and high costs.

The manufacturing process for the probe socket set is performed by molding equipment and comprises a socket base forming step and a positioning frame forming step. In the socket base forming step, a socket base shaped as a flat board and having multiple probe holes arranged in an array is molded via a base mold of the molding equipment. In the positioning frame forming step, the socket base is placed in a frame mold, and a positioning frame surrounding the socket base is molded via the molding equipment.

The manufacturing process in accordance with the present invention is suitable for manufacturing socket components, such as a positioning base, a socket plate, and a socket board of a probe socket set. A flat-board-like socket base with probe holes is firstly formed in the socket base forming step, whereby negative effect on accuracy caused by thickness variation during molding is reduced and accuracy of the socket base is enhanced. A positioning frame surrounding the socket base is formed in the positioning frame forming step, so influence on the dimensional accuracy of the probe holes in the socket base is reduced. The probe socket set with good dimensional accuracy of the probe hole in the socket base is manufactured with low manufacturing cost and a short manufacturing period.

Other objectives, advantages and novel features of the invention will become more apparent from the following detailed description when taken in conjunction with the accompanying drawings.

### BRIEF DESCRIPTION OF THE DRAWINGS

FIG. 1 shows a block diagram of a manufacturing process for a probe socket set in accordance with the present invention;

FIG. 2 shows an operational view of a socket base forming step;

FIG. 3 shows a perspective view of a semi component after the socket base forming step;

FIG. 3A shows an enlarged perspective view of the semi component in FIG. 3;

FIG. 4 shows an operational view of a positioning frame forming step;

FIG. 5 shows a perspective view of a component after the positioning frame forming step;

FIG. 6 shows a cross-sectional side view of the component in FIG. 5;

FIG. 7 shows an exploded perspective view of a probe socket set manufactured by the manufacturing process in accordance with the present invention; and

FIG. 8 shows a cross-sectional side view of the probe socket set in FIG. 7.

### DETAILED DESCRIPTION OF THE PREFERRED EMBODIMENTS

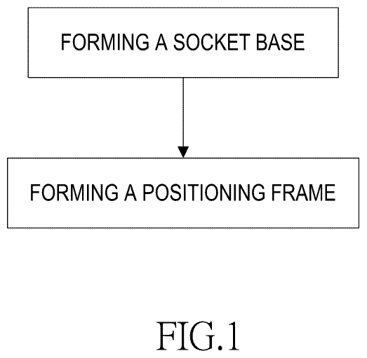

With reference to FIG. 1, an embodiment of a manufacturing process for a probe socket set in accordance with the present invention is performed by molding equipment. The manufacturing process comprises a socket base forming step and a positioning frame forming step.

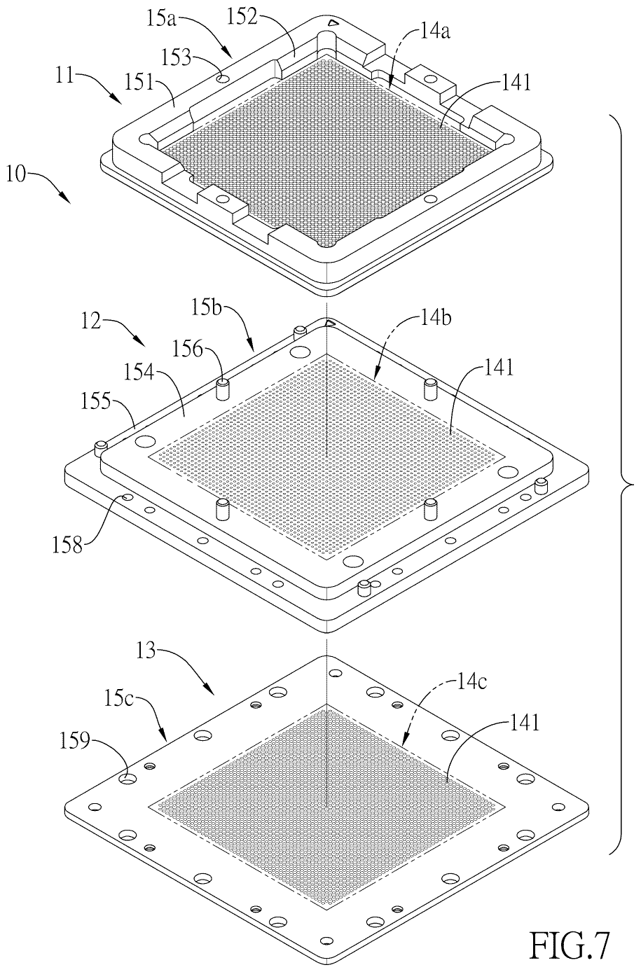

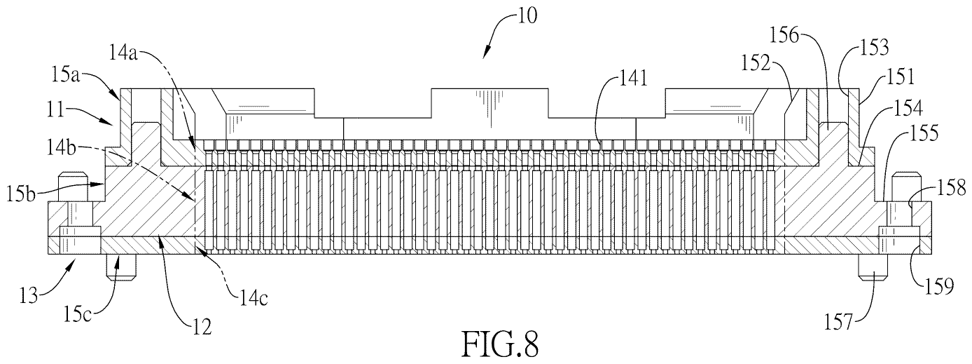

With reference to FIGS. 7 and 8, the manufacturing process is configured for manufacturing respective socket components, such as a positioning base 11, a socket plate 12, and a socket board 13, of a probe socket set 10. The following description will take the manufacturing process of forming the positioning base 11 of the probe socket set 10 as an example.

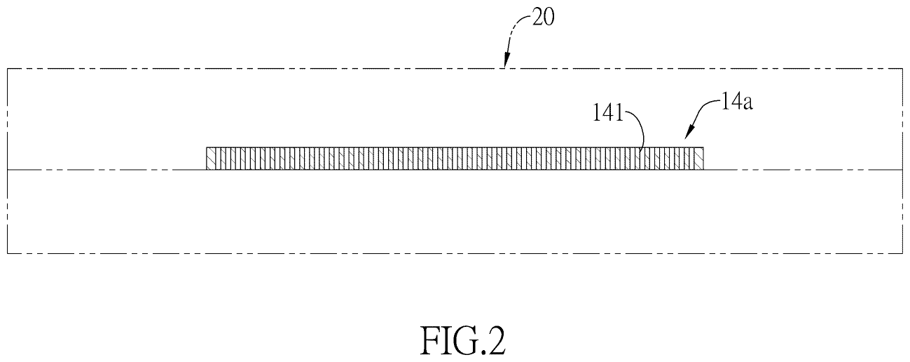

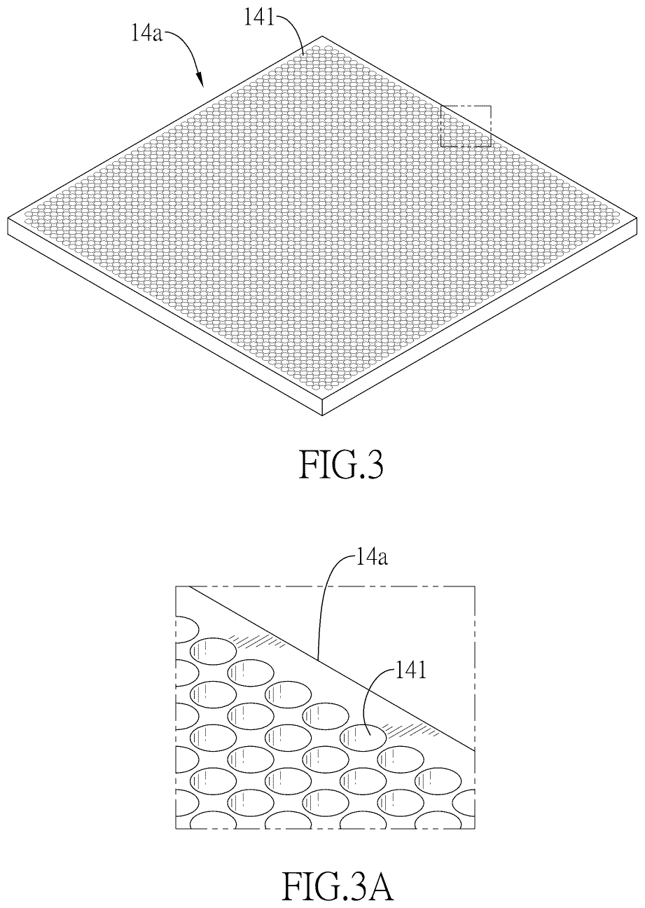

With reference to FIGS. 1, 2, 3, and 3A in the socket base forming step, a socket base 14a shaped as a flat board and having multiple probe holes 141 arranged in an array is molded via a base mold 20 of the molding equipment. After the socket base 14a is formed, the positioning frame forming step is performed.

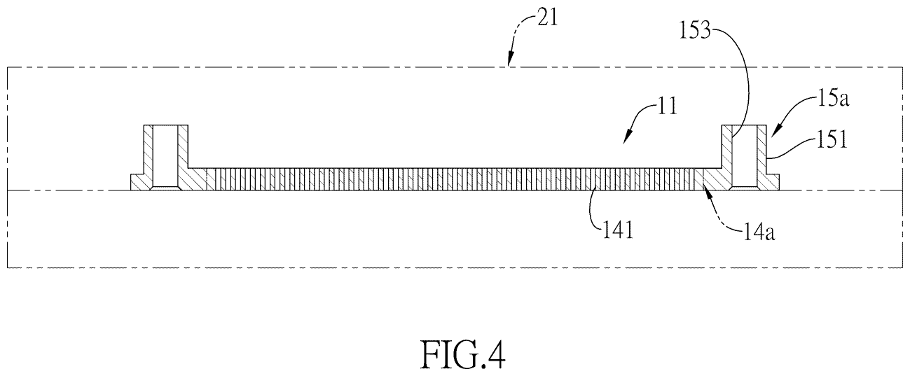

With reference to FIGS. 1 and 4 to 6, in the positioning frame forming step, the socket base 14a is placed in a frame mold 21. A positioning frame 15a surrounding the socket base 14a is molded via the molding equipment.

Wherein, in the socket base forming step and the positioning frame forming step, the socket base 14a and the positioning frame 15a are molded via injection molding. In addition, the socket base 14a and the positioning frame 15a may be made of heat resistant engineering plastics, e.g. polyetheretherketone (PEEK), polyetherimide (PEI), polyamideimide (PAI), polyimide (PI), polyphenylene sulfide (PPS), and so on.

As foregoing, the manufacturing process is suitable for manufacturing the positioning base 11, the socket plate 12, and the socket board 13 of the probe socket set 10. To manufacture socket components such as the positioning base 11, the socket plate 12, or the socket board 13, a respective base mold 20 and a respective frame mold 21 are selected for forming a respective socket component.

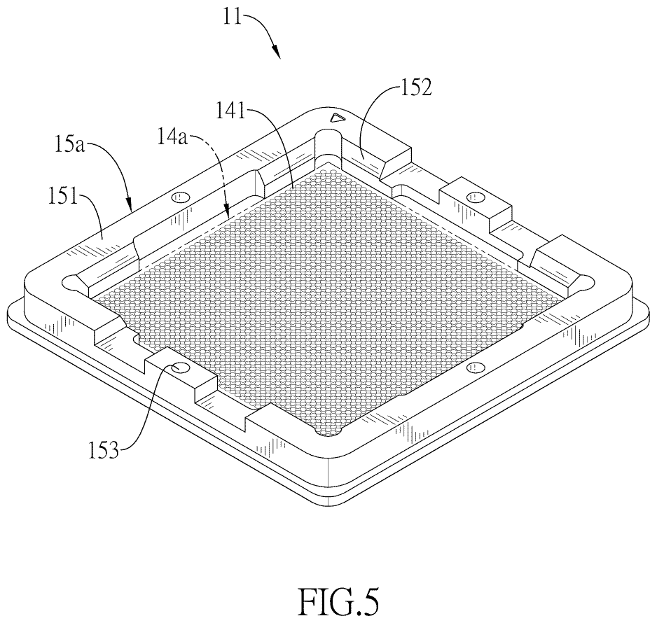

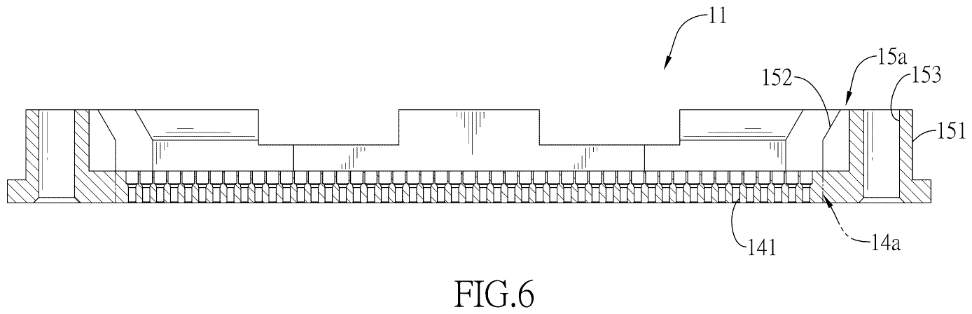

As shown in FIGS. 5 and 6, when the positioning base 11 of the probe socket set 10 is manufactured by the manufacturing process, the positioning frame 15a of the positioning base 11 comprises an external peripheral wall 151, multiple guiding chamfers 152 formed along inner edges of the external peripheral wall 151, and multiple pin holes 153 formed in the external peripheral wall 151.

As shown in FIGS. 7 and 8, when the socket plate 12 of the probe socket set 10 is manufactured by the manufacturing process, the positioning frame 15b of the socket plate 12 comprises a frame body 154, a flange 155, multiple pins 156, multiple mounting bosses 157, and multiple positioning holes 158. The frame body 154 surrounds the socket base 14b of the socket plate 12. The flange 155 protrudes from and surrounds the frame body 154. The pins 156 and the mounting bosses 157 respectively protrude from an upper side and a lower side of the positioning frame 15b. The positioning holes 158 are formed in the flange 155.

As shown in FIGS. 7 and 8, when the socket board 13 of the probe socket set 10 is manufactured by the manufacturing process, multiple mounting holes 159 are formed in the positioning frame 15c of the socket board 13.

As shown in FIGS. 7 and 8, the positioning base 11, the socket plate 12, and the socket board 13 are stacked with one another. The socket plate 12 is disposed on the socket board 13 with the mounting bosses 157 of the socket plate 12 being inserted in the mounting holes 159 of the socket board 13, respectively. The positioning base 11 is disposed on the socket plate 12 with the pins 156 of the socket plate 12 being inserted in the pin holes 153 of the positioning base 11. The probe holes 141 in the socket bases 14a, 14b, 14c of the positioning base 11, the socket plate 12, and the socket board 13 are aligned with each other and communicate with each other and are adapted for mounting probes for testing the semiconductor.

With reference to FIGS. 1 to 7, in a molding process, large thickness variation or complex structure of a molded component may result in poor dimensional accuracy of the molded component. In order to enhance the dimensional accuracy of the socket bases 14a, 14b, 14c with probe holes 141 of the socket components of the probe socket set 10, in the manufacturing process in accordance with the present invention, each socket component is distinguished into a flat-board like the socket base 14a/14b/14c and a positioning frame 15a/15b/15c surrounding the socket base 14a/14b/14c with great thickness variation. In the step of forming a socket base, the socket base 14a/14b/14c with less thickness variation and simple structure is formed firstly, thereby lowering the negative effect on accuracy caused by thickness variations and structural complexity. As a result, dimensional accuracy of the probe holes 141 of the socket base 14a/14b/14c is enhanced. In the positioning frame forming step, the positioning frame 15a/15b/15c surrounding the socket base 14a/14b/14c is formed, and influence on the dimensional accuracy of the probe holes 141 in the socket base 14a/14b/14c is reduced. Accordingly, the probe socket set 10 with good dimensional accuracy of the probe holes 141 in the socket base 14a/14b/14c is manufactured with low manufacturing cost and a short manufacturing period.

In summary, in the manufacturing process for the probe socket set in accordance with the present invention, a flat-board like socket base 14a/14b/14c with multiple probe holes 141 is formed by the socket base forming step, thereby promoting the dimensional accuracy of the probe holes 141 in the socket base 14a/14b/14c. After that, a positioning frame 15a/15b/15c surrounding the socket base 14a/14b/14c is formed by the positioning frame forming step. As a result, the probe socket set 10 having the probe holes 141 in the socket base 14a, 14b, 14c with good dimensional accuracy is manufactured with low manufacturing cost and a short manufacturing period.

What is claimed is:

1. A manufacturing process for a probe socket set performed by molding equipment comprising:
a socket base forming step: molding a socket base shaped as a flat board and having multiple probe holes arranged in an array via a base mold of the molding equipment; and
a positioning frame forming step: placing the socket base in a frame mold and molding a positioning frame surrounding the socket base via the molding equipment.

2. The manufacturing process as claimed in claim 1, wherein in the socket base forming step and the positioning frame forming step, the socket base and the positioning frame are molded via injection molding.

3. The manufacturing process as claimed in claim 1, wherein the socket base and the positioning frame are made of heat resistant engineering plastics.

4. The manufacturing process as claimed in claim 2, wherein the socket base and the positioning frame are made of heat resistant engineering plastics.

5. The manufacturing process as claimed in claim 1, wherein the positioning frame comprises an external peripheral wall, multiple guiding chamfers formed along inner edges of the external peripheral wall, and multiple pin holes formed in the external peripheral wall.

6. The manufacturing process as claimed in claim 2, wherein the positioning frame comprises an external peripheral wall, multiple guiding chamfers formed along inner edges of the external peripheral wall, and multiple pin holes formed in the external peripheral wall.

7. The manufacturing process as claimed in claim 3, wherein the positioning frame comprises an external peripheral wall, multiple guiding chamfers formed along inner edges of the external peripheral wall, and multiple pin holes formed in the external peripheral wall.

8. The manufacturing process as claimed in claim 4, wherein the positioning frame comprises an external peripheral wall, multiple guiding chamfers formed along inner edges of the external peripheral wall, and multiple pin holes formed in the external peripheral wall.

9. The manufacturing process as claimed in claim 1, wherein the positioning frame comprises
a frame body surrounding the socket base;
a flange protruding from and surrounding the frame body;
multiple pins and multiple mounting bosses protruding from an upper side and a lower side of the positioning frame; and
multiple positioning holes formed in the flange.

10. The manufacturing process as claimed in claim 2, wherein the positioning frame comprises
a frame body surrounding the socket base;
a flange protruding from and surrounding the frame body;
multiple pins and multiple mounting bosses protruding from an upper side and a lower side of the positioning frame; and
multiple positioning holes formed in the flange.

11. The manufacturing process as claimed in claim 3, wherein the positioning frame comprises
a frame body surrounding the socket base;
a flange protruding from and surrounding the frame body;
multiple pins and multiple mounting bosses protruding from an upper side and a lower side of the positioning frame; and
multiple positioning holes formed in the flange.

12. The manufacturing process as claimed in claim 4, wherein the positioning frame comprises
a frame body surrounding the socket base;
a flange protruding from and surrounding the frame body;
multiple pins and multiple mounting bosses protruding from an upper side and a lower side of the positioning frame; and
multiple positioning holes formed in the flange.

13. The manufacturing process as claimed in claim 1, wherein the positioning frame comprises multiple mounting holes.

14. The manufacturing process as claimed in claim 2, wherein the positioning frame comprises multiple mounting holes.

15. The manufacturing process as claimed in claim 3, wherein the positioning frame comprises multiple mounting holes.

16. The manufacturing process as claimed in claim 4, wherein the positioning frame comprises multiple mounting holes.
